(19) United States
(12) Patent Application Publication
(10) Pub. No.: US 2025/0185285 A1
(43) Pub. Date: Jun. 5, 2025

(54) SEMICONDUCTOR DEVICE AND MANUFACTURING METHOD OF SEMICONDUCTOR DEVICE

(71) Applicant: Mitsubishi Electric Corporation, Tokyo (JP)

(72) Inventors: Akihiro KOYAMA, Tokyo (JP); Toshiaki IWAMATSU, Tokyo (JP)

(73) Assignee: Mitsubishi Electric Corporation, Tokyo (JP)

(21) Appl. No.: 18/840,521

(22) PCT Filed: Mar. 3, 2022
(86) PCT No.: PCT/JP2022/009146

§ 371 Date: Aug. 22, 2024

(51) Int. Cl. H10D 30/66; H10D 30/01; H10D 62/10; H10D 64/27; H10D 64/68

(52) U.S. Cl. CPC H10D 30/665; H10D 30/668; H10D 62/102; H10D 64/516; H10D 64/518; H10D 64/683; H10D 30/0297

(57) ABSTRACT

A semiconductor device includes: a drift layer of first conductivity type; a well region of second conductivity type on the drift layer; an impurity region of first conductivity type on the well region; a gate trench extending through the impurity region, well region, and drift layer; a termination trench connected to the gate trench, wider than the gate trench; a gate dielectric film on insides of the gate and termination trenches; a first gate electrode inside the gate and termination trenches; a field dielectric film on the first gate electrode in the termination trench, covering above a top corner of the termination trench farther from the gate trench; and a second gate electrode on tops of the field dielectric film and the first gate electrode, overlying the field dielectric film, thereby preventing destruction of the gate dielectric film on the top corner in a lead-out portion.

### TECHNICAL FIELD

The present disclosure relates to a trench gate type semiconductor device and its manufacturing method, in particular to a structure of an outer peripheral side gate electrode of the semiconductor device.

### BACKGROUND TECHNOLOGY

In power control applications for automotive equipment, industrial equipment, etc., semiconductor devices with a trench gate structure, such as an insulated gate bipolar transistor (IGBT) and a metal oxide semiconductor field effect transistor (MOSFET), are used.

A semiconductor device with a trench gate structure includes a gate electrode lead-out portion in a trench formed by extending a gate trench of an active region, through which a main current flows, to a terminal region outside the active region. Patent document 1 disclosed a technique for relaxing an electric field concentration occurring on a dielectric film at a trench top corner farther from an active region by forming the dielectric film on the gate electrode lead-out portion and opening the dielectric film on the trench with high precision to connect the gate electrode to a gate pad.

### PRIOR ART DOCUMENTS

### Patent Documents

[Patent Document 1] Japanese Unexamined Patent Application Publication (Translation of PCT Application) No. 2006-520091 (see FIG. 7C)

### SUMMARY OF THE INVENTION

### Problems to be Solved by the Invention

However, when opening the dielectric film on the trench at the gate lead-out portion, which is described in Patent Document 1, in some cases, an unintended opening such as a misaligned opening or a non-perpendicular opening may unfortunately thin the dielectric film at the trench top corner farther from the active region, in the gate lead-out portion. In this case, in an ON state of the semiconductor device, when a voltage exceeding a threshold voltage is applied to the gate electrode, an electric field concentration on the dielectric film provided at the trench top corner farther from the active region, in the gate lead-out portion, may lead to destruction of the dielectric film.

The present disclosure is made to solve the above-mentioned problem and to provide a semiconductor device in which destruction of the dielectric film provided at the trench top corner farther from the active region, in the gate lead-out portion, is prevented.

### Means to Solve the Problems

A semiconductor device according to the present disclosure includes: a drift layer of a first conductivity type; a well region of a second conductivity type provided on a surface of the drift layer; an impurity region of the first conductivity type provided on a surface of the well region; a gate trench extending from a surface of the impurity region, passing through the well region, and reaching the drift layer; a termination trench connected to the gate trench, a width of the termination trench in an extension direction of the gate trench being wider than a width of the gate trench in a plan view; a gate dielectric film formed in contact with inner sides of the gate trench and the termination trench; a first gate electrode formed inside the gate trench and the termination trench via the gate dielectric film; a field dielectric film thicker than the gate dielectric film and formed in contact with the first gate electrode formed in the termination trench, to cover above a top corner of the termination trench farther from the gate trench in the extension direction and extending from an inside to an outside of the termination trench; and a second gate electrode in contact with a top of the field dielectric film and a top of the first gate electrode formed in the termination trench and overlying the field dielectric film from the inside to the outside of the termination trench in the extension direction.

A manufacturing method of a semiconductor device according to the present disclosure includes: forming a drift layer of a first conductivity type; providing a well region of a second conductivity type on a surface of the drift layer; providing an impurity region of the first conductivity type on a surface of the well region; providing a gate trench extending from a surface of the impurity region, passing through the well region, and reaching the drift layer; providing a termination trench connected to the gate trench, a width of the termination trench in an extension direction of the gate trench being wider than a width of the gate trench in a plan view; forming a gate dielectric film in contact with inner sides of the gate trench and the termination trench; forming a first gate electrode inside the gate trench and the termination trench via the gate dielectric film; forming a field dielectric film made thicker than the gate dielectric film and in contact with the first gate electrode formed in the termination trench, to cover above a top corner of the termination trench farther from the gate trench in the extension direction and extending from an inside to an outside of the termination trench; and forming a second gate electrode in contact with a top of the field dielectric film and a top of the first gate electrode formed in the termination trench and overlying the field dielectric film from the inside to the outside of the termination trench in the extension direction.

### Effects of the Invention

According to the present disclosure, a semiconductor device can be obtained in which destruction of the dielectric film provided at a termination trench top corner farther from the active region, in the gate lead-out portion, is prevented.

### BRIEF DESCRIPTION OF THE DRAWINGS

FIG. 1 is a planar schematic diagram showing an outline configuration of a semiconductor device according to Embodiment 1.

FIG. 2 is a schematic diagram showing an outline configuration of the semiconductor device according to Embodiment 1.

FIG. 3 is a schematic cross-sectional diagram showing an outline configuration of the semiconductor device according to Embodiment 1.

FIG. 4 is an explanatory diagram of a manufacturing method of the semiconductor device according to Embodiment 1.

FIG. 5 is an explanatory diagram of a manufacturing method of the semiconductor device according to Embodiment 1.

FIG. 6 is an explanatory diagram of a manufacturing method of the semiconductor device according to Embodiment 1.

FIG. 7 is an explanatory diagram of a manufacturing method of the semiconductor device according to Embodiment 1.

FIG. 8 is an explanatory diagram of a manufacturing method of the semiconductor device according to Embodiment 1.

FIG. 9 is a planar schematic diagram showing an outline configuration of a variation example of the semiconductor device according to Embodiment 1.

FIG. 10 is a schematic diagram showing an outline configuration of a semiconductor device according to Embodiment 2.

FIG. 11 is a schematic diagram showing an outline configuration of the semiconductor device according to Embodiment 2.

FIG. 12 is a planar schematic diagram showing an outline configuration of a semiconductor device according to Embodiment 3

FIG. 13 is a schematic diagram showing an outline configuration of the semiconductor device according to Embodiment 3.

### MODES FOR CARRYING OUT THE INVENTION

Hereinafter, the present disclosure and the embodiments will be described in detail on the basis of drawings. The drawings are shown schematically, and the sizes and the positional relationships of the components shown in the different drawings may be changed as appropriate. Further, details of semiconductor layers and electrodes may be omitted to provide a concise description of the drawings. Additionally, terms such as upper, lower, side, bottom, front, or back which refer to a specific position and direction are used for convenience and have no bearing on their use in implementation.

In the description of the embodiments of the present disclosure, it is assumed that in the semiconductor, the first conductivity type is n-type and the second conductivity type is p-type, whereas the first conductivity type may be p-type and the second conductivity type may be n-type. Also, it is assumed that the semiconductor device is a MOSFET, whereas it may be an IGBT. In addition, it is assumed that the material used for a semiconductor substrate and a drift layer is silicon carbide (SiC), whereas it may be silicon, a material with a larger bandgap than silicon such as nitride gallium and diamond, or a combination thereof.

### Embodiment 1

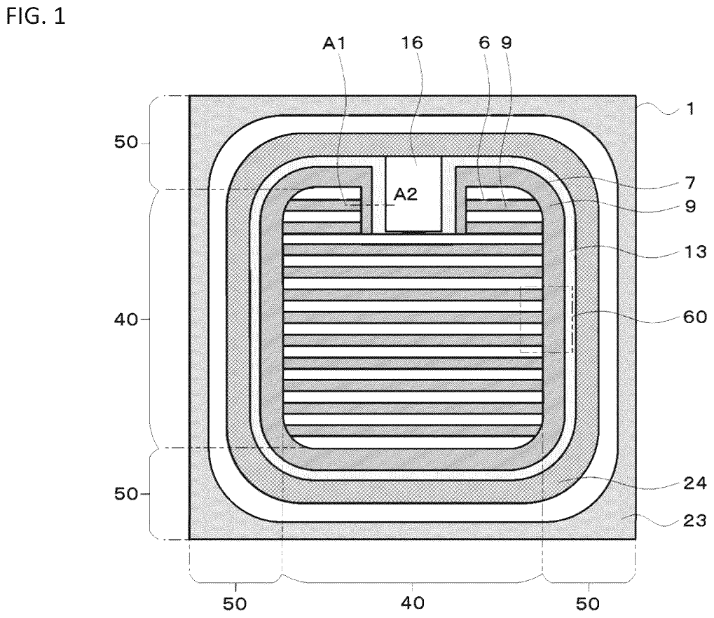

First, a configuration of a semiconductor device according to the present embodiment will be described. FIG. 1 is a planar schematic diagram showing an outline configuration of a semiconductor device according to the present embodiment. As shown in FIG. 1, the semiconductor device includes an active region 40, which is a region in which a main current flows when the semiconductor device is in an operating state, and a termination region 50, which is a region outside the active region 40. Here, for the sake of concise description, illustrations of a field dielectric film 10, a top-surface electrode 20, etc., are omitted.

The active region 40 includes a gate trench 6 and a first gate electrode 9, both of which are provided in stripes. The termination region 50 includes a termination trench 7 connected to the gate trench 6, and a first gate electrode 9 and further includes a second gate electrode 13 connected to the first gate electrode 9 in the direction perpendicular to the page. The termination region 50 includes a gate pad 16 connected to the second gate electrode 13. The boundary between the active region 40 and the termination region 50 is defined as an interface, in a plan view, between the gate trench 6 and the termination trench 7 and a location of the gate pad 16.

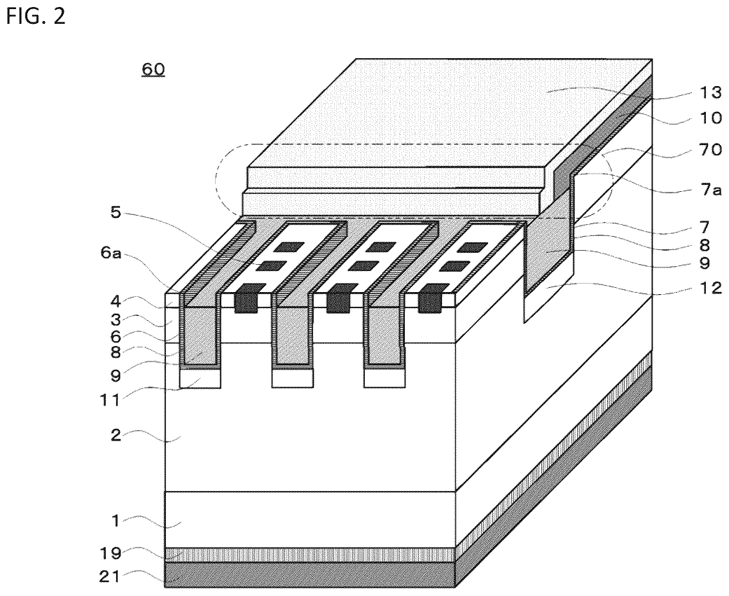

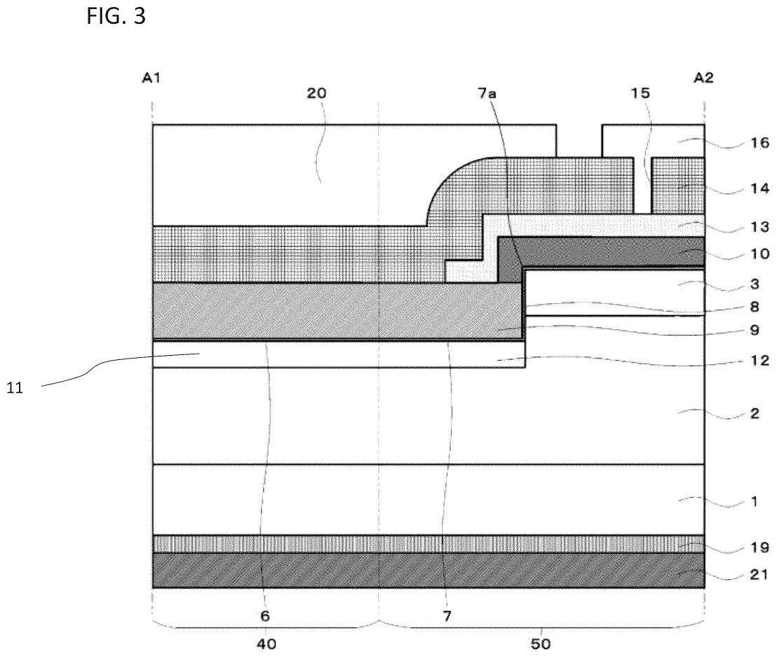

FIG. 2 is a schematic diagram showing an outline configuration of the semiconductor device according to the present embodiment and is a perspective view of cross sections and a top of the sub-region 60 in FIG. 1. FIG. 3 is a schematic cross-sectional diagram showing an outline configuration of the semiconductor device according to Embodiment 1 and shows a cross section taken along the line A1-A2 in FIG. 1.

As shown in FIG. 2, on the front side of the semiconductor substrate 1, the semiconductor device includes a drift layer 2, a well region 3, an impurity region 4, a contact region 5, a gate trench 6, a gate dielectric film 8, and a first gate electrode 9 and further includes a termination trench 7, the field dielectric film 10, a first electric field relaxation region 11, a second electric field relaxation region 12, and a second gate electrode 13. As shown in FIG. 2, on the back side of the semiconductor substrate 1, the semiconductor device includes a bottom-surface ohmic electrode 19 and a bottom-surface electrode 21.

In a gate lead-out portion 70 where the second gate electrode 13 is provided, a termination trench top corner 7a farther from the gate trench 6 is covered by the field dielectric film 10 thicker than the gate dielectric film 8, and the second gate electrode 13 is provided in such a manner as to overlie the field dielectric film 10 from the top of the first gate electrode 9.

The drift layer 2 is provided on the semiconductor substrate 1 made of an n-type silicon carbide and is made of an n-type silicon carbide. The n-type impurity of the drift layer 2 should be nitrogen or phosphorus, and the impurity concentration of the drift layer 2 should be approximately between 1×10¹⁴ cm⁻³ and 1×10¹⁷ cm⁻³. The thickness of the drift layer 2 should be approximately between 5 μm and 200 μm.

The well region 3 is a p-type region provided on the surface of the drift layer 2 and is made of silicon carbide. The p-type impurity of the well region 3 should be aluminum, boron, or gallium, and the impurity concentration of the well region 3 should be approximately between 1×10¹⁵ cm⁻³ and 1×10²⁰ cm⁻³. The impurity concentration of the well region 3 may or may not be constant in the depth direction. The thickness of the well region 3 should be approximately between 0.3 μm and 3 μm.

The impurity region 4 is an n-type region provided on the surface of the well region 3 and is made of silicon carbide. The impurity region 4 is a source region in other words. The n-type impurity of the impurity region 4 should be nitrogen or phosphorus, and the impurity concentration of the impurity region 4 should be approximately between 1×10¹⁸ cm⁻³ and 1×10²¹ cm⁻³. The thickness of the impurity region 4 should be equal to or less than the thickness of the well region 3.

The contact region 5 is a p-type region provided on the surface of the well region 3 and is made of silicon carbide. The contact region 5 is connected to the impurity region 4 and a top-surface ohmic electrode 18, which will be described later. The contact region 5 allows a path to be connected from the impurity region 4 to the top-surface ohmic electrode 18 via the contact region 5, thereby improving the electrical connection in the path from the impurity region 4 to the top-surface ohmic electrode 18.

The p-type impurity of the contact region 5 should be aluminum, boron, or gallium, and the impurity concentration of the contact region 5 should be approximately between 1×10¹⁸ cm⁻³ and 1×10²² cm⁻³. The thickness of the contact region 5 should be equal to or less than the thickness of the well region 3. Although the semiconductor device in the example includes the contact region 5, it may not be provided.

The gate trench 6 is an excavation that extends from the surface of the impurity region 4, passes through the well region 3, and reaches the drift layer 2. As shown in FIG. 1, the gate trench 6 is provided in stripes, that is, in parallel in the active region 40. The stripes of the gate trench 6 improve the performance of the semiconductor device because a plane with high channel mobility such as (1-100) plane can be used as a channel in the case where the semiconductor device according to the present embodiment is configured as a trench gate MOSFET using silicon carbide for the semiconductor substrate 1 and the drift layer 2. The gate trench 6 extends in the direction from the active region 40 to the termination region 50. Hereinafter, this direction of extension may be referred to as the extension direction of the gate trench 6.

The width of the gate trench 6 refers to the width in the left-right direction of the front side cross section in FIG. 2 and should be approximately between 1 μm and 10 μm. When the gate trench 6 is tapered in a cross-sectional view, the width of the gate trench 6 refers to the width of the widest part of the tapered shape. The depth of the gate trench 6 should be approximately between 1 μm and 6 μm.

The termination trench 7 is an excavation that is connected to the gate trench 6 in a plan view, with its width in the extension direction of the gate trench 6 wider than the width of the gate trench 6. The termination trench 7 can be provided by extending the gate trench 6 in a plan view. The depth of the termination trench 7 may or may not be the same as the depth of the gate trench 6. The width of the termination trench 7 in the extension direction of the gate trench 6 should be equal to or less than 3 times the width of the gate trench 6, for example greater than 1 μm and equal to or less than 30 μm.

By selecting the width of the termination trench 7 as described above, the above of the termination trench top corner 7a farther from the gate trench 6 can be easily covered with the field dielectric film 10, which will be described later, and the gate lead-out portion 70 can be easily formed. In other words, it is possible to connect the first gate electrode 9 provided in the termination trench 7 and the second gate electrode 13, which will be described later, without using a process of opening the field dielectric film 10 with high precision. Further, it is possible to prevent the first gate electrode 9 from disappearing and causing disconnection in an etch-back process of the first gate electrode 9, which will be described later. As shown in FIG. 2 or 3, the termination trench top corner 7a is located at the boundary between the inside and the outside of the termination trench 7 and includes a corner portion of the termination trench 7 and its vicinity region where the gate dielectric film 8 can be formed. That is, the termination trench top corner 7a includes a part of the inside and a part of the outside of the termination trench 7, in other words, it includes the vicinity of the termination trench top corner 7a.

The gate dielectric film 8 is provided on the inner sides of the gate trench 6 and the termination trench 7 and is made of silicon dioxide. As shown in FIG. 2, within the gate trench 6 and the termination trench 7, the gate dielectric film 8 should be aligned with or lower than the positions of a gate trench top corner 6a and the termination trench top corner 7a, respectively. The thickness of the gate dielectric film 8 should be approximately between 10 nm and 100 nm. As shown in FIG. 2 or 3, the gate dielectric film 8 may be formed outside the gate trench 6 or the termination trench 7, for example, on the well region 3 or the impurity region 4 of the termination region 50. The gate dielectric film 8 formed on the well region 3 of the termination region 50 covers the termination trench top corner 7a.

The first gate electrode 9 is formed inside the gate trench 6 and the termination trench 7 via the gate dielectric film 8 and is made of a conductive material such as polysilicon. As shown in FIG. 2, within the gate trench 6 and the termination trench 7, the upper end of the first gate electrode 9 may be aligned with or lower than the positions of the gate trench top corner 6a and the termination trench top corner 7a, respectively.

With the upper end of the first gate electrode 9 located below the gate trench top corner 6a and the termination trench top corner 7a, an electric field applied to the gate dielectric film 8 in the vicinity of the gate trench top corner 6a and the termination trench top corner 7a is relaxed and destruction of the gate dielectric film 8 can be prevented in an operating state of the semiconductor device.

The field dielectric film 10 is formed extending from the inside to the outside of the termination trench 7, being in contact with the first gate electrode 9 formed in the termination trench 7, and covering the above of the termination trench top corner 7a farther from the gate trench 6 in the extension direction of the gate trench 6. In other words, the field dielectric film 10 is formed continuously from the top surface of the first gate electrode 9 to the top surface of the outer peripheral side of the termination trench 7, covering the termination trench top corner 7a. FIG. 3 shows an example in which the field dielectric film 10 is provided on the first gate electrode 9 of the termination region 50 and on the gate dielectric film 8 which overlaps with the termination trench top corner 7a and the well region 3. The thickness of the field dielectric film 10 should be greater than the thickness of the gate dielectric film 8, for example between 0.1 μm and 5.0 μm.

Between the configuration in which the field dielectric film 10 thicker than the gate dielectric film 8 covers the above of the termination trench top corner 7a farther from the gate trench 6 and the configuration in which only the gate dielectric film 8 covers the same termination trench top corner 7a, the former is more effective in reducing the electric field applied to the gate dielectric film 8 provided in the vicinity of the termination trench top corner 7a and in suppressing the destruction of the gate dielectric film 8. The field dielectric film 10 two times or more thicker than the gate dielectric film 8 is more effective in suppressing the destruction of the gate dielectric film 8. The field dielectric film 10 may be made of a dielectric material such as silicon dioxide.

The first electric field relaxation region 11 is a p-type region provided below the bottom of the gate trench 6 and is made of silicon carbide. The first electric field relaxation region 11 has a conductivity type opposite to that of the drift layer 2 and is capable of relaxing the electric field applied to the gate dielectric film 8 provided on the bottom surface of the gate trench 6 and preventing the destruction of the gate dielectric film 8 in the operating state of the semiconductor device. The depth of the first electric field relaxation region 11 should be approximately between 0.1 μm and 2.0 μm downward from the bottom of the gate trench 6. The first electric field relaxation region 11 may be in contact with the bottom surface of the gate trench 6. The p-type impurity of the first electric field relaxation region 11 should be aluminum, boron, or gallium, and the impurity concentration of the first electric field relaxation region 11 should be approximately between 1×10¹⁵ cm−³ and 1×10¹⁹ cm⁻³.

The second electric field relaxation region 12 is a p-type region provided below the bottom surface of the termination trench 7 and is made of silicon carbide. The second electric field relaxation region 12 has a conductivity type opposite to that of the drift layer 2 and is capable of relaxing the electric field applied to the gate dielectric film 8 provided on the bottom surface of the termination trench 7 and preventing the destruction of the gate dielectric film 8 in the operating state of the semiconductor device. The depth of the second electric field relaxation region 12 should be approximately between 0.1 μm and 2.0 μm downward from the bottom of the termination trench 7. The second electric field relaxation region 12 may be in contact with the bottom surface of the termination trench 7. The p-type impurity of the second electric field relaxation region 12 should be aluminum, boron, or gallium, and the impurity concentration of the first electric field relaxation region 11 should be approximately between 1×10¹⁵ cm⁻³ and 1×10¹⁹ cm⁻³.

The second gate electrode 13 is in contact with the top of the field dielectric film 10 and the top of the first gate electrode 9 provided in the termination trench 7 and overlies the field dielectric film 10 from the inside to the outside of the termination trench 7 in the extension direction of the gate trench 6. That is, the second gate electrode 13 is continuously provided from the top surface of the first gate electrode 9 to the top surface of the field dielectric film 10 beyond the step at the end of the field dielectric film 10 and covers the end of the field dielectric film 10 on the termination trench 7. The second gate electrode 13 may be made of the same material as the first gate electrode 9, for example polysilicon, or may be made of a different material from the first gate electrode 9, for example a metal material such as aluminum. The second gate electrode 13 made of a different material from the first gate electrode 9 is easy to manufacture.

As shown in FIG. 3, the second gate electrode 13 is the wiring for connecting the first gate electrode 9 provided in the termination trench 7 to the gate pad 16. The gate pad 16 is provided on the second gate electrode 13 outside the termination trench 7 and is connected to the second gate electrode 13 via a gate contact hole 15 provided in an interlayer dielectric film 14 made of silicon dioxide. The gate pad 16 is provided also on the top of the interlayer dielectric film 14. A configuration in which the second gate electrode 13 and the gate pad 16 are connected outside the termination trench 7 improves margins in selecting the location and dimensions of the gate contact hole 15.

As shown in FIG. 3, the top-surface electrode 20 is separated from the gate pad 16 and is provided on the interlayer dielectric film 14. The top-surface electrode 20 is made of a metal material such as aluminum.

The bottom-surface ohmic electrode 19 is provided on the back side of the semiconductor substrate 1 and is made of a reaction product of a metal film containing nickel as a principal component with the semiconductor substrate 1, for example, nickel silicide. The bottom-surface electrode 21 is provided in contact with the bottom-surface ohmic electrode 19 and is made of titanium, nickel, silver, gold, aluminum, etc.

As described above, the semiconductor device according to the present embodiment is configured.

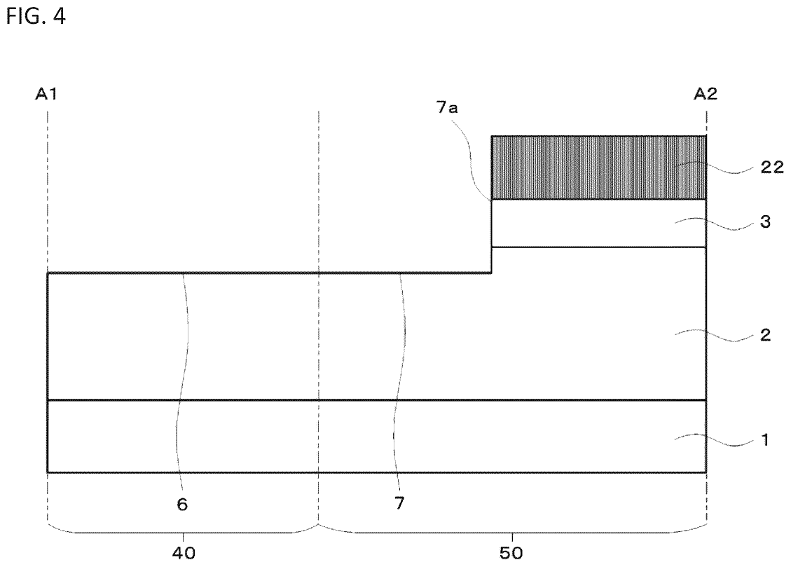

Next, a manufacturing method of the semiconductor device according to the present embodiment will be described using FIGS. 4 to 8. FIGS. 4 to 8 show an explanatory diagram at each manufacturing stage of the semiconductor device, and correspond to the cross sections taken along the line A1-A2 in FIG. 1. First, a manufacturing method of the semiconductor device up to the state shown in FIG. 4 will be described without using the diagrams.

The semiconductor substrate 1 made of an n-type silicon carbide having a 4H polytype is prepared, and an n-type drift layer 2 is epitaxially grown on the front surface of the semiconductor substrate 1 by chemical vapor deposition (CVD) or the like. Next, using a resist mask formed by photolithography on the drift layer 2, aluminum, boron, or gallium is ion implanted to provide a p-type well region 3 on the surface of the drift layer 2. The well region 3 may be provided by epitaxial growth.

Next, using the resist mask formed by photolithography on the well region 3, nitrogen or phosphorus is ion implanted to provide an n-type impurity region 4, in other words, the source region, on the surface of the well region 3. Next, using the resist mask formed on the well region 3 and the impurity region 4, aluminum, boron, or gallium is ion implanted to provide a p-type contact region 5 on the surface of the well region 3. The heating temperature of the semiconductor substrate 1 during ion implantation should be 150° C. or higher. The heating temperature of 150° C. or higher lowers the electrical resistance of the contact region 5, and the resistance loss of the semiconductor device in the operating state can be reduced.

Next, a silicon dioxide film having a thickness approximately between 1 μm and 2 μm is formed on the well region 3, the impurity region 4, and the contact region 5, and then an etching mask 22 having openings at the locations corresponding to the gate trench 6 and the termination trench 7 is formed by reactive ion etching (RIE). Then, the gate trench 6 and the termination trench 7 are formed by RIE. In this way, the state shown in FIG. 4 is reached.

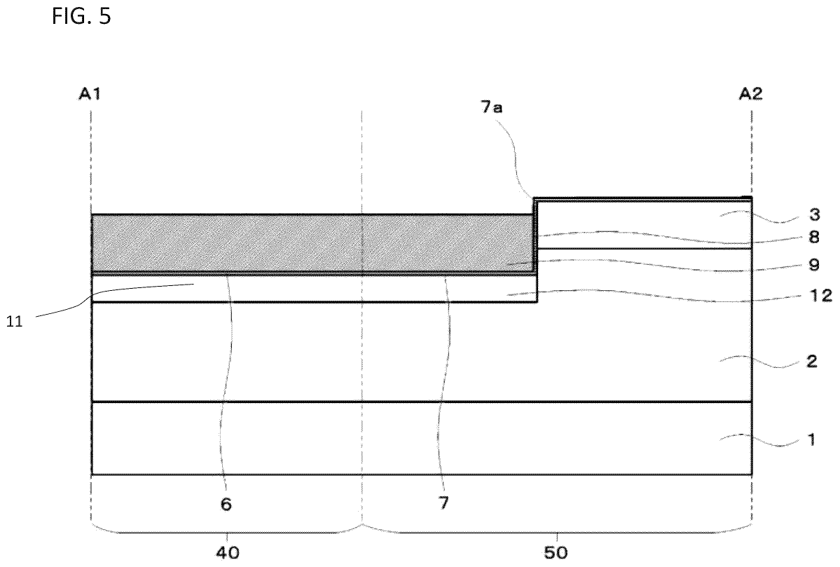

FIG. 5 shows a state in which the first electric field relaxation region 11 and the second electric field relaxation region 12 are provided below the gate trench 6 and the termination trench 7, respectively, and the gate dielectric film 8 and the first gate electrode 9 are formed within the gate trench 6 and the termination trench 7.

In the state of FIG. 4, aluminum, boron, or gallium is ion implanted to provide the first electric field relaxation region 11 and the second electric field relaxation region 12 below the gate trench 6 and the termination trench 7, respectively. Then, after removing the etching mask 22, an annealing process is performed to activate the ion-implanted impurities. The annealing process is performed in an inert gas atmosphere such as argon or vacuum at a temperature approximately between 1500° C. and 1900° C. for approximately 30 seconds to 1 hour. To prevent deterioration of the silicon carbide due to high-temperature heating, that is, surface roughening, a carbon film may be formed on the silicon carbide before the annealing process.

Then, on the surface of the drift layer 2 including the insides of the gate trench 6 and the termination trench 7 and on the surface of the well region 3 of the termination region 50, the gate dielectric film 8 is formed by a thermal oxidation method or a CVD method, etc., and then polysilicon to become the first gate electrode 9 is formed by a CVD method, etc. Further, the polysilicon is etched by the etch-back process to form the first gate electrode 9 below (inclusive) the positions of the gate trench top corners 6a and the termination trench top corner 7a within the gate trench 6 and the termination trench 7, respectively. In this way, the state shown in FIG. 5 is reached.

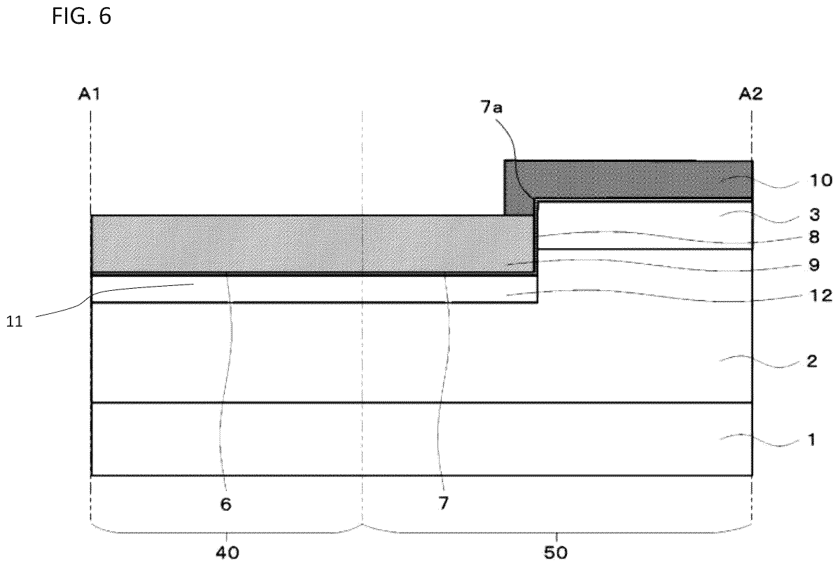

FIG. 6 shows a state in which the field dielectric film 10 covers the above of the termination trench top corner 7a farther from the gate trench 6.

In the state of FIG. 5, a dielectric film such as silicon dioxide to become the field dielectric film 10 is formed by a CVD method, etc., and then a resist mask is formed on the dielectric film by photolithography. Then, the dielectric film is etched and opened to form the field dielectric film 10, and then the resist mask is removed. In this way, the state shown in FIG. 6 is reached.

The field dielectric film 10 may be formed by patterning the dielectric film by RIE, by wet etching using a hydrofluoric acid, etc., or by a combination thereof. In forming the field dielectric film 10, as compared to using dry etching which requires precise opening of the dielectric film, using RIE or wet etching as described above makes manufacturing easier or allows precise forming of the field dielectric film 10 to protect the termination trench top corner 7a. In addition, as compared to forming the field dielectric film 10 by selective oxidation (LOCOS: Local Oxidation of Silicon), the formation time can be shortened, and the manufacturing cost can be reduced.

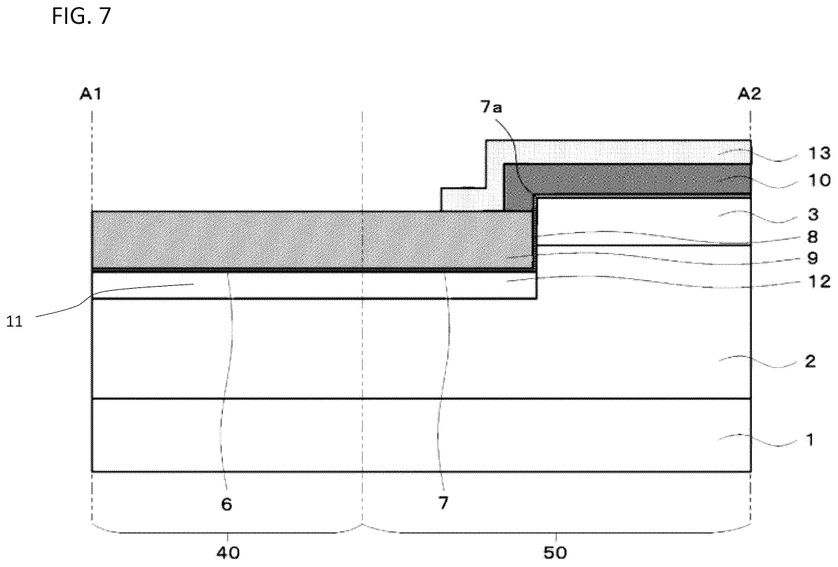

FIG. 7 shows a state in which the second gate electrode 13 is formed on the first gate electrode 9 and the field dielectric film 10 covering the above of the termination trench top corner 7a.

In the state of FIG. 6, a conductive material such as polysilicon, which becomes the second gate electrode 13, is formed by a CVD method, etc., and a resist mask is formed on the polysilicon by photolithography. Next, the polysilicon is etched to form the second gate electrode 13, and then the resist mask is removed. In this way, the state shown in FIG. 7 is reached.

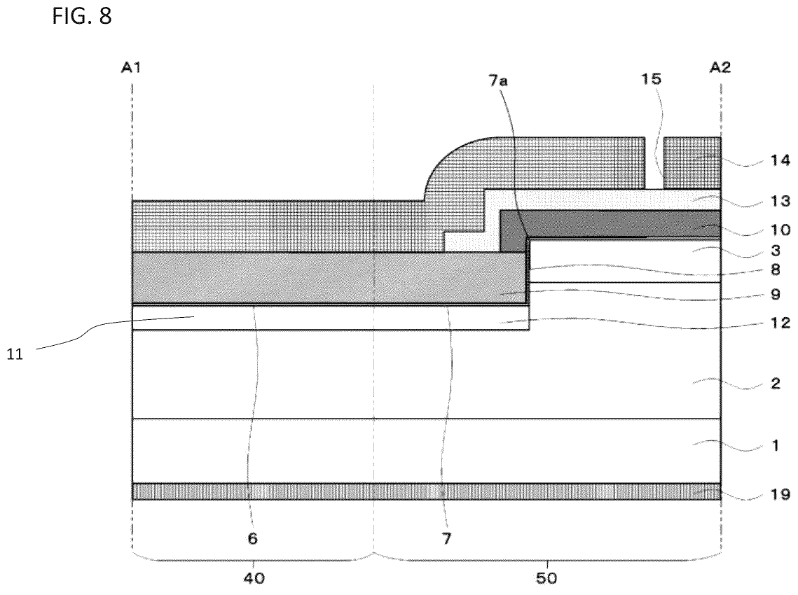

FIG. 8 shows a state in which the interlayer dielectric film 14 with the gate contact hole 15 and the bottom-surface ohmic electrode 19 are formed.

In the state shown in FIG. 7, the interlayer dielectric film 14 is formed on the first gate electrode 9 and the second gate electrode 13 by a low pressure CVD method, etc., and a resist mask is formed on the interlayer dielectric film 14 by photolithography. Next, in the active region 40 (not shown), the interlayer dielectric film 14 is etched to provide a source contact hole 17, which will be described later, and a metal film is formed in such a manner as to be in contact with the impurity region 4 and the contact region 5 and annealed to form the top-surface ohmic electrode 18, which will be described later. Then, the metal film on the interlayer dielectric film 14 is removed by etching, and then the resist mask is removed. Also, a metal film is formed on the back side of the semiconductor substrate 1 and annealed to form the bottom-surface ohmic electrode 19. The heating temperature for each annealing process should be approximately between 600° C. and 1100° C.

Then, a resist mask is formed by photolithography on the top of the interlayer dielectric film 14. Next, the interlayer dielectric film 14 located outside the termination trench 7 is etched to provide the gate contact hole 15 which reaches the second gate electrode 13, and then the resist mask is removed. In this way, the state shown in FIG. 8 is reached.

Then, a metal film such as aluminum is formed on the interlayer dielectric film 14 and inside the gate contact hole 15 by a sputtering method or a vapor deposition method, etc., and a resist mask is formed on the metal film by photolithography. Next, the metal film is separated by etching to form the gate pad 16 and the top-surface electrode 20, and then the resist mask is removed. Finally, the bottom-surface electrode 21 is formed on the bottom-surface ohmic electrode 19 by a sputtering method or a vapor deposition method, etc.

As described above, the semiconductor device in FIG. 3 is manufactured.

Next, the operation of the semiconductor device according to the present embodiment will be described.

When a voltage equal to or higher than a threshold voltage is applied between the gate pad 16 and the top-surface electrode 20, a channel is formed in the well region 3 facing the first gate electrode 9, and electrons flow from the impurity region 4 to the drift layer 2. When a voltage is applied between the top-surface electrode 20 and the bottom-surface electrode 21 and thus an electric field is generated, electrons reach the bottom-surface electrode 21 via the drift layer 2 and the semiconductor substrate 1, that is, a current flows from the bottom-surface electrode 21 to the top-surface electrode 20, so that the semiconductor device becomes an ON state.

An electric field is generated at the gate dielectric film 8 in the vicinity of the gate trench top corner 6a and the termination trench top corner 7a. However, because the first gate electrode 9 is provided to be aligned with or lower than the positions of the gate trench top corner 6a and the termination trench top corner 7a, and the field dielectric film 10 is provided to cover the above of the termination trench top corner 7a farther from the gate trench 6, the electric field generated at the gate dielectric film 8 in the vicinity of the gate trench top corner 6a and the termination trench top corner 7a is suppressed and the destruction of the gate dielectric film 8 is prevented. In particular, in the above of the termination trench top corner 7a farther from the gate trench 6, the second gate electrode 13 is provided via the field dielectric film 10 thicker than the gate dielectric film 8, so that the electric field generated at the gate dielectric film 8 in the gate lead-out portion 70 is suppressed, thereby preventing the gate dielectric film 8 from being destroyed.

On the other hand, when a voltage below the threshold voltage is applied between the gate pad 16 and the top-surface electrode 20, the channel is no longer formed in the well region 3 facing the first gate electrode 9, no current flows from the bottom-surface electrode 21 to the top-surface electrode 20, and the semiconductor device becomes an OFF state. In an OFF state of the semiconductor device, a voltage higher than the voltage in an ON state is applied between the top-surface electrode 20 and the bottom-surface electrode 21, and a depletion layer spreads from the well region 3 to the drift layer 2.

The depletion layer extends downward from the first electric field relaxation region 11 and the second electric field relaxation region 12, that is, to the drift layer 2. Therefore, the destruction of the gate dielectric film 8 at the bottom surfaces or the bottom corners of the gate trench 6 and the termination trench 7 caused by the electric field due to the high voltage applied between the top-surface electrode 20 and the bottom-surface electrode 21 is suppressed.

When the semiconductor device changes from the OFF state to the ON state, the voltage applied between the top-surface electrode 20 and the bottom-surface electrode 21 decreases, and the depletion layer that had spread to the drift layer 2 shrinks.

As described above, the semiconductor device according to the present embodiment operates by alternately repeating the ON state and the OFF state.

By configuring a semiconductor device in this way, it is possible to obtain the semiconductor device capable of preventing the destruction of the gate dielectric film 8 provided on the termination trench top corner 7a farther from the gate trench 6 in the gate lead-out portion 70. Further, as compared to using dry etching which requires precise opening of the dielectric film, such a configuration makes manufacturing easier or allows precise forming of the field dielectric film 10 to protect the termination trench top corner 7a. In addition, as compared to forming the field dielectric film 10 by selective oxidation (LOCOS: Local Oxidation of Silicon), the formation time can be shortened, and the manufacturing cost can be reduced. Furthermore, since the field insulating film 10 can be formed by patterning through wet etching, over-etching of the first gate electrode 9 is suppressed when etching the field insulating film 10.

As shown in FIG. 1, the second gate electrode 13 may be provided to surround the gate trench 6 in a plan view. The termination trench 7 or the field dielectric film 10 may be provided to completely surround the gate trench 6 or, alternatively, to surround it with intermittent portions in a plan view.

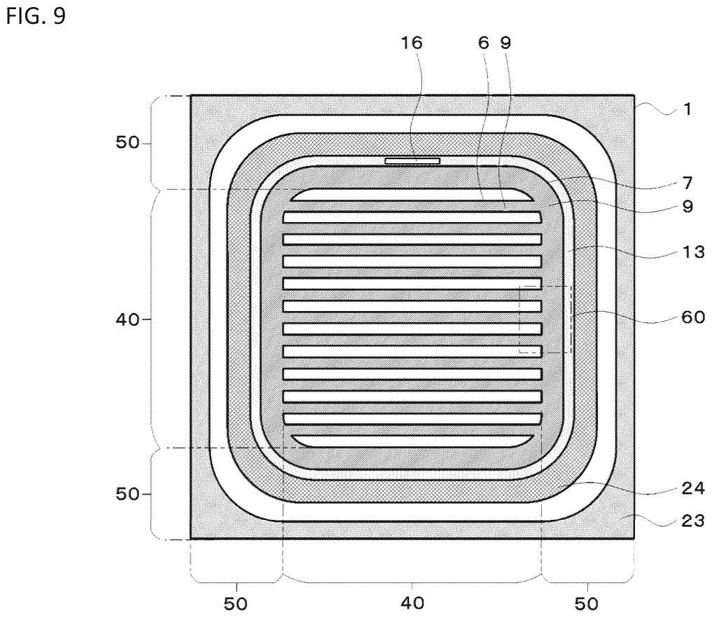

In FIG. 1, the termination trench 7 is provided on the side of the gate pad 16 in a plan view, but may not be provided on the side. For example, as shown in FIG. 9, the termination trench 7 may continuously surround the gate trench 6 in a plan view at a location corresponding to the gate pad 16 in FIG. 1 without interrupting it. In this case, the gate pad 16 should be connected to the second gate electrode 13 via the gate contact hole 15 provided in the interlayer dielectric film 14 (not shown) on the second gate electrode 13 outside the termination trench 7. Alternatively, in at least a portion of the termination region 50 such as the sub-region 60 in FIG. 9, gate wiring may be formed within the gate contact hole 15 provided in the interlayer dielectric film 14 (not shown) and on the interlayer dielectric film 14 and extended along the second gate electrode 13 or the interlayer dielectric film 14 in a plan view to be connected to the gate pad 16. In this case, the gate wiring can be easily formed by forming and etching a metal film simultaneously with forming the gate pad 16.

Further, as shown in FIG. 1, the termination region 50 may be provided with a channel stop region 23 to suppress the expansion of the depletion layer to an edge of the semiconductor device. The channel stop region 23 is an n-type region provided on an outer peripheral side of the termination trench 7 and is made of silicon carbide. The n-type impurity of the channel stop region 23 should be nitrogen or phosphorus, and the impurity concentration of the channel stop region 23 should be approximately between 1×10¹⁸ cm⁻³ and 1×10²¹ cm⁻³. The thickness of the channel stop region 23 may be the same as or different from the thickness of the impurity region 4. The channel stop region 23 should be provided by ion implantation and may be formed simultaneously with or before/after the formation of the impurity region 4 by using the resist mask for providing the impurity region 4.

As shown in FIG. 1, the termination region 50 may include a peripheral electric field relaxation region 24, such as a field limiting ring (FLR), continuously or intermittently surrounding the active region 40. For example, a p-type peripheral electric field relaxation region 24 may be provided continuously to surround the active region 40 by implanting aluminum, boron, etc. to a depth of about 0.2 to 3 μm, which does not exceed the thickness of the drift layer 2, from the surface of the drift layer 2. The concentration of the p-type impurity in the peripheral electric field relaxation region 24 should exceed the impurity concentration in the drift layer 2 and should be between 1×10¹⁵ cm^{-3 and} 1×10¹⁹ cm⁻³, inclusive.

The order of the process of forming the well region 3 and the process of forming the impurity region 4 may be swapped. The well region 3 and the impurity region 4 may be provided by first forming the impurity region 4 by ion implanting an n-type impurity on the surface of the well region 3, second forming a resist mask on the impurity region 4 by photolithography, and then forming the well region 3 by ion implanting a p-type impurity in a region other than the impurity region 4.

Although the thickness of the etching mask 22 and the RIE process are adjusted such that the etching mask 22 remains after the formation of the gate trench 6 and the termination trench 7, the first electric field relaxation region 11 and the second electric field relaxation region 12 may be formed by completely removing the etching mask 22 and ion implanting the p-type impurity using a resist mask formed by photolithography.

The first electric field relaxation region 11 may be formed simultaneously with the formation of the second electric field relaxation region 12, or before/after the formation of the first electric field relaxation region 11. The first electric field relaxation region 11 and the well region 3 may be electrically connected via a semiconductor layer provided by ion implanting a p-type impurity from a diagonal direction with respect to the opening of the gate trench 6 and forming a p-type semiconductor layer within the drift layer 2 in contact with the side of the gate trench 6. Electrically connecting the first electric field relaxation region 11 to the well region 3 improves the frequency characteristics of the semiconductor device compared to leaving the first electric field relaxation region 11 floating.

If the semiconductor device is an IGBT, although the examples have shown cases of MOSFET, the conductivity type of the semiconductor substrate 1 should be p-type, and the semiconductor substrate 1 can be made thinner by polishing.

### Embodiment 2

Although in the examples shown in Embodiment 1, the second gate electrode 13 is not branched at the junction between the first gate electrode 9 and the second gate electrode 13, in the examples of the present embodiment, the second gate electrode 13 is branched, that is, includes a plurality of lead-out portions separated from each other. The rest of the configuration is the same as in Embodiment 1.

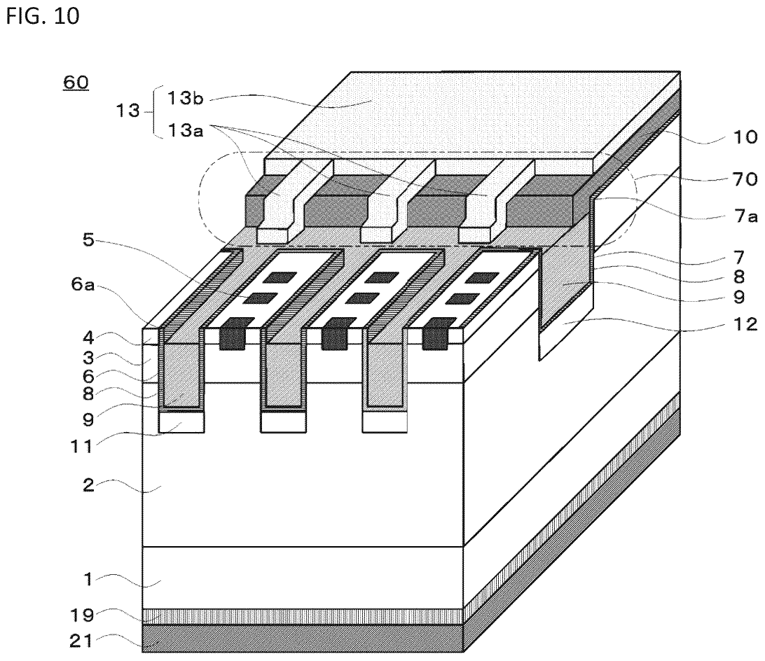

FIG. 10 is a schematic diagram showing an outline configuration of the semiconductor device according to the present embodiment, and corresponds to a perspective view of the cross-section and top of the sub-region 60 in FIG. 1. As shown in FIG. 10, the second gate electrode 13 includes second gate electrode lead-out portions 13a and a second gate electrode outer periphery 13b, and the second gate electrode lead-out portions 13a, branched from the second gate electrode outer periphery 13b, are connected to the first gate electrode 9.

The plurality of second gate electrode lead-out portions 13a are provided such that they are separated from each other, in contact with the top of the field dielectric film 10 and the top of the first gate electrode 9 provided in the termination trench 7, and overlie the field dielectric film 10 from the inside to the outside of the termination trench 7 in the extension direction of the gate trench 6. That is, the second gate electrode lead-out portions 13a are continuously provided from the top surface of the first gate electrode 9 to the top surface of the field dielectric film 10 beyond the step at the end of the field dielectric film 10 and cover the end of the field dielectric film 10 on the termination trench 7. Further, as shown in FIG. 10, in the region where the plurality of second gate electrode lead-out portions 13a are separated, the end of the field dielectric film 10 is exposed.

The second gate electrode outer periphery 13b is provided on the field dielectric film 10 to be in contact with the second gate electrode lead-out portions 13a. The second gate electrode outer periphery 13b is a wiring that connects the first gate electrode 9 provided in the termination trench 7 to the gate pad 16 via the second gate electrode lead-out portions 13a. The second gate electrode outer periphery 13b is connected to the gate pad 16 via the gate contact hole 15 which reaches the second gate electrode 13 provided on the interlayer dielectric film 14 outside the termination trench 7. The gate pad 16 is provided also on the top of the interlayer dielectric film 14. The gate contact hole 15 may be provided to the interlayer dielectric film on the second gate electrode lead-out portions 13a.

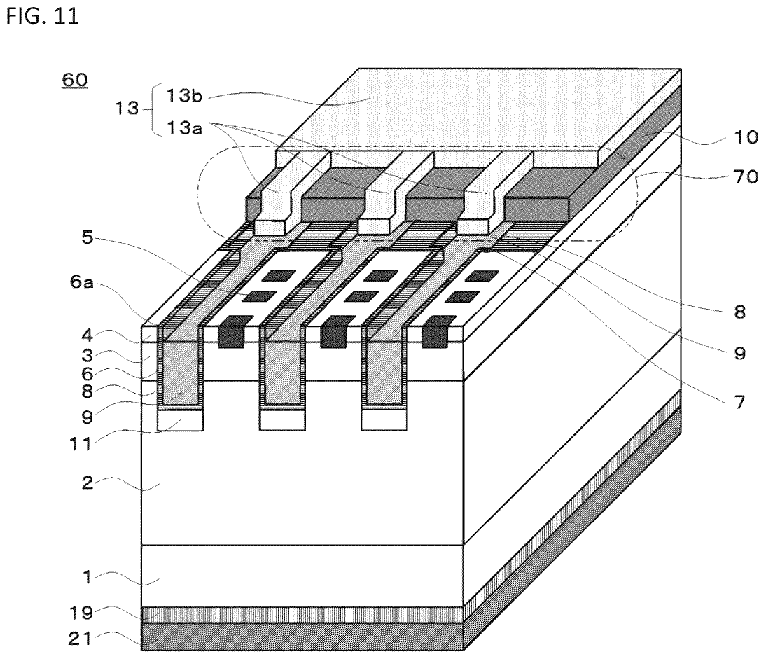

The semiconductor device configured in this way also produces the same effects as in Embodiment 1. The configuration in which the plurality of second gate electrode lead-out portions 13a are separated from each other allows the termination trench 7 to be provided as separate trenches as shown in FIG. 11 which corresponds to a perspective view of the cross-section and top of the sub-region 60 in FIG. 1. In other words, the termination trench 7 can be intermittently provided to surround the active region 40 including the gate trench 6. When the first gate electrode 9 is formed within the termination trench 7 by etching back, this configuration allows the etching back to be performed in the same manner as for the gate trench 6 connected to the separated termination trenches 7, thereby suppressing the disappearing of the first gate electrode 9 due to the etching back.

### Embodiment 3

Although in the examples shown in Embodiment 1, the gate trench 6 is provided in stripes in a plan view, in the examples of the present embodiment, the gate trench 6 is provided in grids. The rest of the configuration is the same as in Embodiment 1.

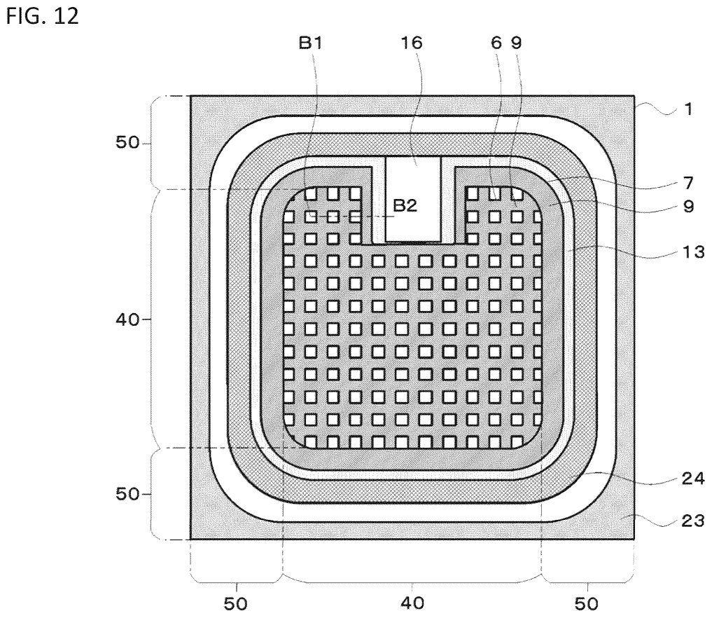

FIG. 12 is a planar schematic diagram showing an outline configuration of a semiconductor device according to the present embodiment. As shown in FIG. 12, the gate trench 6 is provided in grids in the active region 40, and first gate electrodes 9 are provided within the gate trenches 6. Although the plurality of gate trenches 6 are provided in grids formed by lines intersecting at right angles throughout the active region 40, they may have portions that are formed by lines not orthogonal to each other, i.e., they may be provided in a staggered manner.

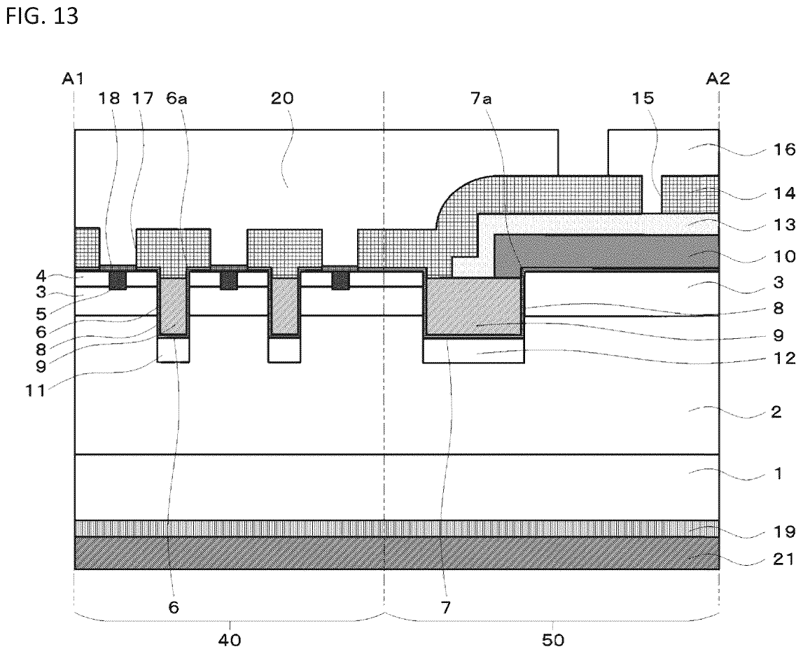

FIG. 13 is a schematic diagram showing an outline configuration of the semiconductor device according to the present embodiment, and shows a cross section taken along the line B1-B2 in FIG. 12. As shown in FIG. 13, even when the gate trenches 6 are provided in grids, the depth of the gate trenches 6 should preferably be the same as or approximately the same as the depth of the termination trenches 7. FIG. 13 shows an example in which, in the active region 40, the source contact hole 17 is provided to the interlayer dielectric film 14, and the contact region 5 and the top-surface ohmic electrode 18, which is in contact with the top of the contact region 5, are provided. However, the contact region 5 and the top-surface ohmic electrode 18 are not necessarily provided. The top-surface ohmic electrode 18 is made of a reaction product formed from a nickel-based metal film and the semiconductor substrate 1, such as nickel silicide.

The semiconductor device configured in this way also produces the same effects as in Embodiment 1. Compared to the stripe configuration, the grid configuration of the gate trenches 6 is more effective in suppressing the power loss due to the resistance of the first gate electrodes 9 during the switching operation of the semiconductor device.

The description of each of the embodiments in the present disclosure may include substances, materials, dimensions, shapes, relative arrangement relationships, implementation conditions, etc. of the components. However, these are only examples and do not limit the embodiments.

In addition, within the scope of each embodiment, countless examples of non-exemplified variations may be contemplated. They include, for instance, modifications, additions, and omissions of any component. They also include combinations of the components extracted from each of the embodiments.

Each component of the invention may be provided alone or in a plurality as long as there is no conflict in each of the embodiments. Furthermore, each component of the invention is a conceptual unit, so that it may consist of a plurality of structures or correspond to a part of a structure.

### DESCRIPTION OF SYMBOLS

1 . . . semiconductor substrate,
2 . . . drift layer,
3 . . . well region,
4 . . . impurity region,
5 . . . contact region,
6 . . . gate trench,
6a . . . gate trench top corner
7 . . . termination trench,
7a . . . termination trench top comer,
8 . . . gate dielectric film,
9 . . . first gate electrode,
10 . . . field dielectric film,
11 . . . first electric field relaxation region,
12 . . . second electric field relaxation region,
13 . . . second gate electrode,
13a . . . second gate electrode lead-out portion,
13b . . . second gate electrode outer periphery,
14 . . . interlayer dielectric film,
15 . . . gate contact hole,
16 . . . gate pad,
17 . . . source contact hole,
18 . . . top-surface ohmic electrode,
19 . . . bottom-surface ohmic electrode,
20 . . . top-surface electrode,
21 . . . bottom-surface electrode,
22 . . . etching mask,
23 . . . channel stop region,
24 . . . peripheral electric field relaxation region,
40 . . . active region,
50 . . . terminal region,
60 . . . subregion,
70 . . . gate lead-out portion

1. A semiconductor device comprising:
a drift layer of a first conductivity type;
a well region of a second conductivity type provided on a surface of the drift layer;
an impurity region of the first conductivity type provided on a surface of the well region;
a gate trench extending from a surface of the impurity region, passing through the well region, and reaching the drift layer;
a termination trench connected to the gate trench, a width of the termination trench in an extension direction of the gate trench being wider than a width of the gate trench in a plan view;
a gate dielectric film provided in contact with inner sides of the gate trench and the termination trench;
a first gate electrode provided on inner walls and bottom surfaces of the gate trench and the termination trench via the gate dielectric film;
a field dielectric film thicker than the gate dielectric film and provided in contact with the first gate electrode provided in the termination trench, to cover above a top corner of the termination trench farther from the gate trench in the extension direction and extending from an inside to an outside of the termination trench; and
a second gate electrode in contact with a top of the field dielectric film and a top of the first gate electrode provided in the termination trench and overlying the field dielectric film from the inside to the outside of the termination trench in the extension direction,
wherein the field dielectric film does not cover above a top corner of the termination trench closer to the gate trench.

2. The semiconductor device according to claim 1, wherein the second gate electrode comprises:
a plurality of second gate electrode lead-out portions provided separately from each other, in contact with the top of the field dielectric film and the top of the first gate electrode provided in the termination trench, and overlying the field dielectric film from the inside to the outside of the termination trench in the extension direction; and
a second gate electrode outer periphery provided above the field dielectric film and in contact with the second gate electrode lead-out portions.

3. The semiconductor device according to claim 1, further comprising a gate pad connected to the second gate electrode via a gate contact hole provided in an interlayer dielectric film outside the termination trench and reaching the second gate electrode.

4. The semiconductor device according to claim 1, wherein the second gate electrode surrounds the gate trench in a plan view.

5. The semiconductor device according to claim 1, wherein the width of the termination trench in the extension direction is equal to or less than three times the width of the gate trench.

6. The semiconductor device according to claim 1, wherein a thickness of the field dielectric film is equal to or greater than two times a thickness of the gate dielectric film.

7. The semiconductor device according to claim 1, wherein an upper end of the first gate electrode provided in the termination trench is lower than an upper end of the termination trench in a cross-sectional view.

8. The semiconductor device according to claim 1, wherein the first gate electrode and the second gate electrode are made of materials different from each other.

9. The semiconductor device according to claim 1, wherein the gate trench is provided in a stripe or grid shape.

10. The semiconductor device according to claim 1, wherein an electric field relaxation region of the second conductivity type is provided below at least one of the bottom surface of the gate trench and the bottom surface of the termination trench.

11. A manufacturing method of a semiconductor device, comprising:
forming a drift layer of a first conductivity type;
providing a well region of a second conductivity type on a surface of the drift layer;
providing an impurity region of the first conductivity type on a surface of the well region;
providing a gate trench extending from a surface of the impurity region, passing through the well region, and reaching the drift layer;
providing a termination trench connected to the gate trench, a width of the termination trench in an extension direction of the gate trench being wider than a width of the gate trench in a plan view;
forming a gate dielectric film in contact with inner walls and bottom surfaces of the gate trench and the termination trench;
forming a first gate electrode inside the gate trench and the termination trench via the gate dielectric film;
forming a field dielectric film made thicker than the gate dielectric film and in contact with the first gate electrode formed in the termination trench, to cover above a top corner of the termination trench farther from the gate trench in the extension direction and extending from an inside to an outside of the termination trench; and
forming a second gate electrode in contact with a top of the field dielectric film and a top of the first gate electrode formed in the termination trench and overlying the field dielectric film from the inside to the outside of the termination trench in the extension direction,
wherein in forming the field dielectric film, the field dielectric film is formed in such a manner as not to cover above a top corner of the termination trench closer to the gate trench.

12. The manufacturing method of a semiconductor device according to claim 11, wherein the field dielectric film is formed by being patterned by reactive ion etching or wet etching.

13. The manufacturing method of a semiconductor device according to claim 11, wherein the field dielectric film is formed by a CVD method.

14. The manufacturing method of a semiconductor device according to claim 11, wherein the first gate electrode is formed to be lower than an upper end of the termination trench in a cross-sectional view by etching back.

15. The manufacturing method of a semiconductor device according to claim 11, the manufacturing method further comprising:
forming an interlayer dielectric film on the second gate electrode and on the first gate electrode provided in the termination trench;
providing a gate contact hole reaching the second gate electrode in the interlayer dielectric film outside the termination trench; and
forming a gate pad above the second gate electrode and through the gate contact hole.
